(19) United States
(12) Patent Application Publication
(10) Pub. No.: US 2009/0315619 A1
(43) Pub. Date: Dec. 24, 2009

(54) CIRCUIT FOR ADJUSTING CUTOFF FREQUENCY OF FILTER

(75) Inventors: Takeshi Ikeda, Tokyo (JP); Hiroshi Miyagi, Kanagawa (JP)

Correspondence Address: CONNOLLY BOVE LODGE & HUTZ LLP, 1875 EYE STREET, N.W., SUITE 1100, WASHINGTON, DC, 20006, US

(73) Assignee: NEURO SOLUTION CORP., Tokyo (JP)

(21) Appl. No.: 12/097,127

(22) PCT Filed: Jul. 12, 2006
(86) PCT No.: PCT/JP2006/314211

§ 371 Date: Jun. 12, 2008

(30) Foreign Application Priority Data
Dec. 15, 2005 (JP) 2005-362252

(51) Int. Cl. H03K 5/00

(52) U.S. Cl. 327/553

(57) ABSTRACT

A cutoff frequency adjusting circuit includes a filter circuit (1) provided with a plurality of resister elements, and a switch to one of the resister elements, and a capacitor. A cutoff frequency of the filter circuit (1) is determined by a resistor value of the resister element selected by the switch and capacitive value of the capacitor. The cutoff frequency adjusting circuit further includes a clock signal generator (2) that generates first and second frequency clock signals (CK1) and (CK2), and a DSP (3) that compares a level of an output signal output from the filter circuit (1) when the first frequency clock signal (CK 1) is input to the filter circuit (1) and that of an output signal output from the filter circuit (1) when the second frequency clock signal (CK2) is input to the filter circuit (1) and that controls the switch in response to its comparing result.

### TECHNICAL FIELD

The present invention relates to a circuit for adjusting a cutoff frequency of a filter in a semiconductor integrated circuit. More particularly, the present invention is suitable for a circuit for adjusting a cutoff frequency of a filter including a capacitor and a resistor.

### BACKGROUND ART

Conventionally, Filter circuits including capacitors and resistors are used in various electronic circuits. FIG. 1 is a diagram showing an example of the filter circuits. In FIG. 1, reference numeral 101 denotes a differential operational amplifier whose minus input terminal is grounded. Reference numeral 102 denotes a resistor connected to a plus input terminal of the differential operational amplifier 101. Reference numeral 103 denotes a capacitor connected between the plus input terminal and an output terminal of the differential operational amplifier 101. The filter circuit shown in FIG. 1 is a known primary active filter and its cutoff frequency f_{c} is obtained by:

f_{c}=½π(RC)^{1/2}

and depends on a resistor value R of the resistor and a capacitive value C of the capacitor.

Here, the resistor value R and the capacitive value C are set at necessary values for obtaining a desired cutoff frequency. However, in a practical semiconductor process, there is a problem that cutoff frequencies are shifted due to manufacturing variation of resistors and capacitors of filter circuits (variation of the resistor value R and the capacitive value C is on the order of ±30% in a semiconductor process) so that a cutoff frequency standard is not satisfied, resulting in a possibility of defective products. Because of this, it is desirable that cutoff frequencies of filter circuits can be adjusted individually before shipping products manufactured with the filter circuits embedded (for example, radio receivers or the like).

Accordingly, a conventional filter circuit has been proposed in which a plurality of resistors having different resistor values are provided and a resistor value is to be variable by being able to select any of the resistors, thereby being able to adjust a cutoff frequency (for example, see Patent documents 1 and 2).

Patent document 1: Japanese Patent Laid-Open No. 2004-23547

Patent document 2: Japanese Patent Laid-Open No. 2004-303508

### DISCLOSURE OF THE INVENTION

In Patent documents 1 and 2, how to select an optimum resistor value for obtaining a desired cutoff frequency is not disclosed and a method for selecting a resistor value is not clear even though the resistor value can be selected.

Thus, the present invention has an object to be able to appropriately adjust a cutoff frequency of a filter by using a signal processing part such as DSPs (Digital Signal Processor).

In order to solve the problem described above, a circuit for adjusting a cutoff frequency of a filter according to the present invention includes a filter circuit provided with a plurality of resister elements, a switch to select any of a plurality of the resister elements and a capacitor. A cutoff frequency of the filter circuit is determined based on a resistor value of a resister element selected from a plurality of the resister elements by the switch and a capacitive value of the capacitor. The present invention further includes a clock signal generator that generates a first frequency clock signal as a reference and a second frequency clock signal for adjusting; and a signal processing part that compares a first level of a signal output from the filter circuit when the first frequency clock signal is input to the filter circuit with a second level of a signal output from the filter circuit when the second frequency clock signal is input to the filter circuit, and that controls the switch depending on the comparing result.

Also, a plurality of capacitors may be provided instead of a plurality of the resister elements and the cutoff frequency of the filter circuit may be determined based on a capacitive value of a capacitor selected by the switch and a resistor value of the resister element. Similarly to the above case, a cutoff frequency adjustment in this case is also performed by using the clock signal generator and the signal processing part. For example, it is determined whether a difference between the first level and the second level is within a predetermined value or not, and it is determined which of the second level and the predetermined value is greater if the difference is not within the predetermined value and the switch is controlled depending on the determination result.

According to the present invention with the above configuration, it is possible to select an optimum resistor value or capacitive value by using the signal processing part, thereby being able to appropriately adjust a cutoff frequency of a filter.

### BRIEF DESCRIPTION OF THE DRAWINGS

FIG. 1 is a diagram showing an example of a filter circuit;

FIG. 2 is a diagram showing a configuration example of a circuit for adjusting a cutoff frequency of a filter according to an embodiment;

FIG. 3 is a diagram showing a configuration example of a clock signal generator according to the embodiment;

FIG. 4 is a diagram showing a configuration example of a filter circuit according to the embodiment;

FIG. 5 is a diagram showing a frequency characteristic of the filter circuit according to the embodiment;

FIG. 6 is a diagram showing a configuration example of a radio receiver to which the circuit for adjusting a cutoff frequency of a filter according to the embodiment is applied; and

FIG. 7 is a flow chart showing an exemplary operation in an adjusting mode of a cutoff frequency.

### BEST MODE FOR CARRYING OUT THE INVENTION

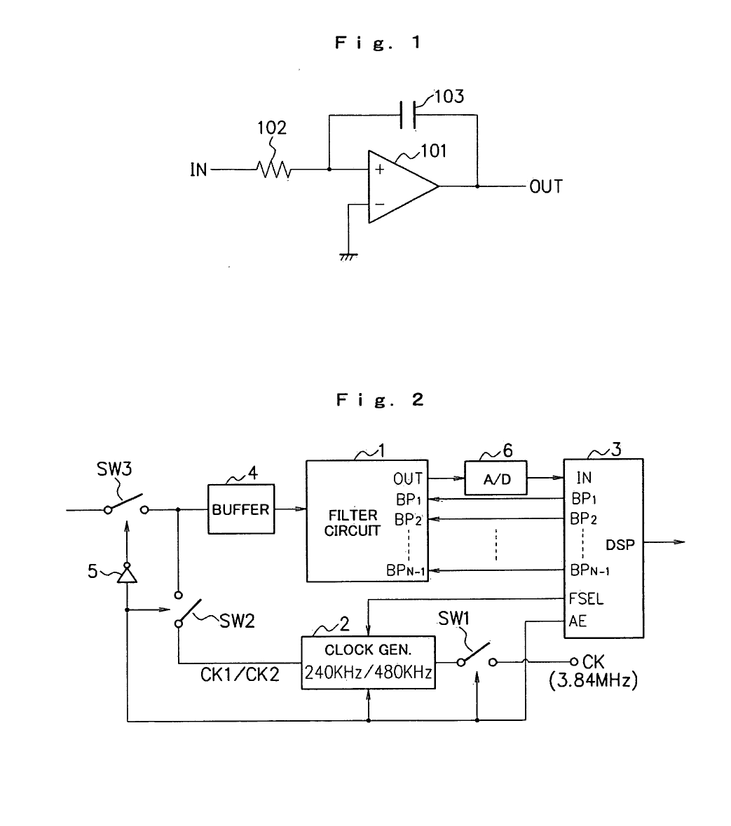

Hereinafter, one embodiment of the present invention is described with reference to the drawings. FIG. 2 is a diagram showing a configuration example of a circuit for adjusting a cutoff frequency of a filter according to the embodiment. As shown in FIG. 2, the circuit for adjusting a cutoff frequency according to the embodiment comprises a filter circuit 1, a clock signal generator 2, a DSP 3 as a signal processing part, a buffer 4, an inverter 5, an A/D converter 6, and a plurality of switches SW1 to SW3. These can be integrated into one chip by, for example, a CMOS (Complementary Metal Oxide Semiconductor) process or a Bi-CMOS (Bipolar-CMOS) process.

The DSP 3 performs an on-off control of the respective switches SW1 to SW3 by a mode control signal AE and controls an operation of the clock signal generator 2 by the mode control signal AE and a frequency switching control signal FSEL. When the mode control signal AE output from the DSP 3 is at “Lo” level; a normal mode is employed in which the first and the second switches SW1 and SW2 are off, and the third switch SW3 is on. On the other hand, when the mode control signal AE is at “Hi” level; an adjusting mode of a cutoff frequency is employed in which the first and the second switches SW1 and SW2 are on, and the third switch SW3 is off.

The clock signal generator 2 sequentially generates a first frequency (for example, 2-40 KHz) clock signal CK1 and a second frequency (for example, 480 KHz) clock signal CK2 when the adjusting mode of the cutoff frequency is set by the DSP 3.

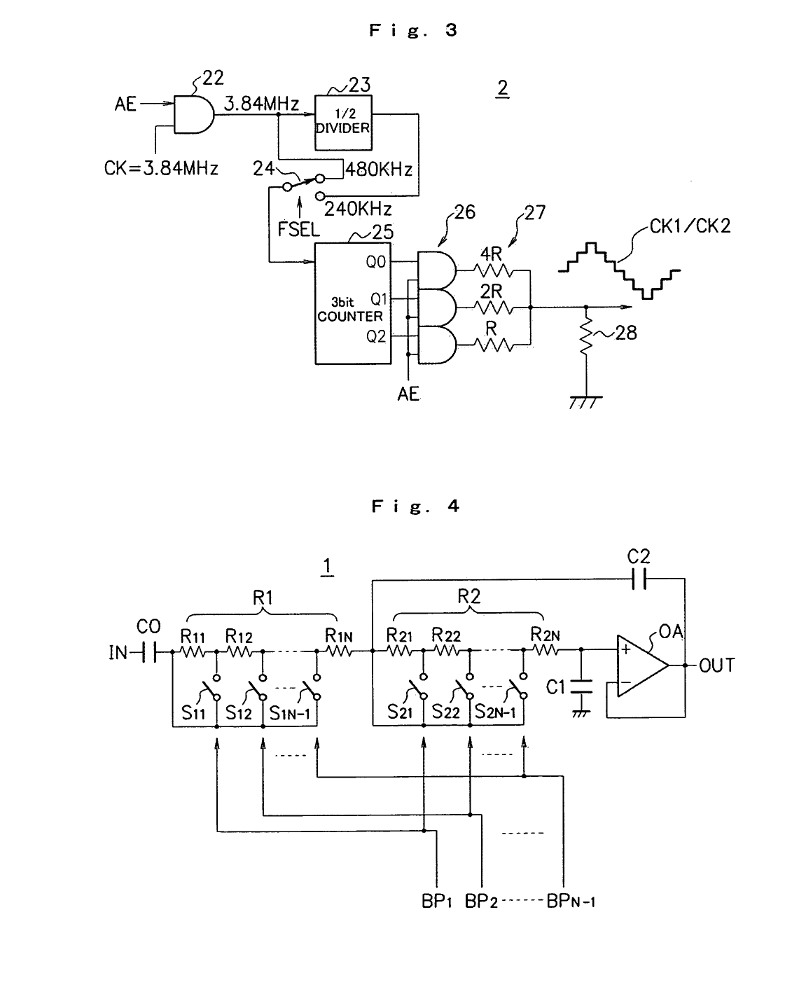

FIG. 3 is a diagram showing a configuration example of the clock signal generator 2. In FIG. 3, reference numeral 22 denotes an AND gate which operates logical multiplication a clock signal CK of a reference frequency (for example, 3.84 MHz) and the mode control signal AE. When the mode control signal AE is at “Hi” level, the clock signal CK passes through the AND gate 22.

Reference numeral 23 denotes a ½ divider circuit dividing the frequency of the clock signal CK (3.84 MHz) into ½. Reference numeral 24 denotes a frequency switching switch whose switching is controlled by the frequency switching control signal FSEL supplied from the DSP 3. A clock signal (undivided signal of 3.84 MHz) supplied from an input terminal of the ½ divider circuit 23 and a clock signal (½ divided signal of 1.92 MHz) supplied from an output terminal of the ½ divider circuit 23 are input to two input terminals of the frequency switching switch 24. When the clock signal CK1 of 240 KHz is generated at the clock signal generator 2, the frequency switching switch 24 selects and outputs the clock signal supplied from the output terminal of the ½ divider circuit 23. On the other hand, when the clock signal CK2 of 480 KHz is generated at the clock signal generator 2, the frequency switching switch 24 selects and outputs the clock signal supplied from the input terminal of the ½ divider circuit 23.

Reference numeral 25 denotes a 3-bit counter performing a count operation based on the clock signal selectively output from the frequency switching switch 24 and outputting a 3-bit count value. Here, reference characters Q0, Q1 and Q2 respectively denote output terminals of a most significant bit, a second bit and a least significant bit. Reference numeral 26 denotes third AND gates each of which is provided to each bit of count values counted by the 3-bit counter 25. The each AND gate 26 corresponding to the each bit operates logical multiplication a value of the each bit output from the 3-bit counter 25 and the mode control signal AE to output the result. In the case of improving voltage accuracy, the number of bits in the counter may be increased.

Reference numeral 27 denotes resistors each of which is provided to three outputs of the third AND gates 26, and a ratio of a resistor value thereof is 4R:2R:R sequentially from the most significant bit. In the case of IC, relative accuracy of the resistances is great. One ends of the three resistors 27 are connected together and a signal at the connecting point is output as the first frequency clock signal CK1 or the second frequency clock signal CK2. Reference numeral 28 denotes a bias resistor applying a bias voltage to the clock signal. The clock signals CK1/CK2 output from the clock signal generator 2 are input to the filter circuit 1 through the second switch SW2 and the buffer 4 shown in FIG. 2.

Note that while the circuit in FIG. 3 is shown as a configuration example of the clock signal generator 2 here, this is only an example and the present invention is not limited thereto.

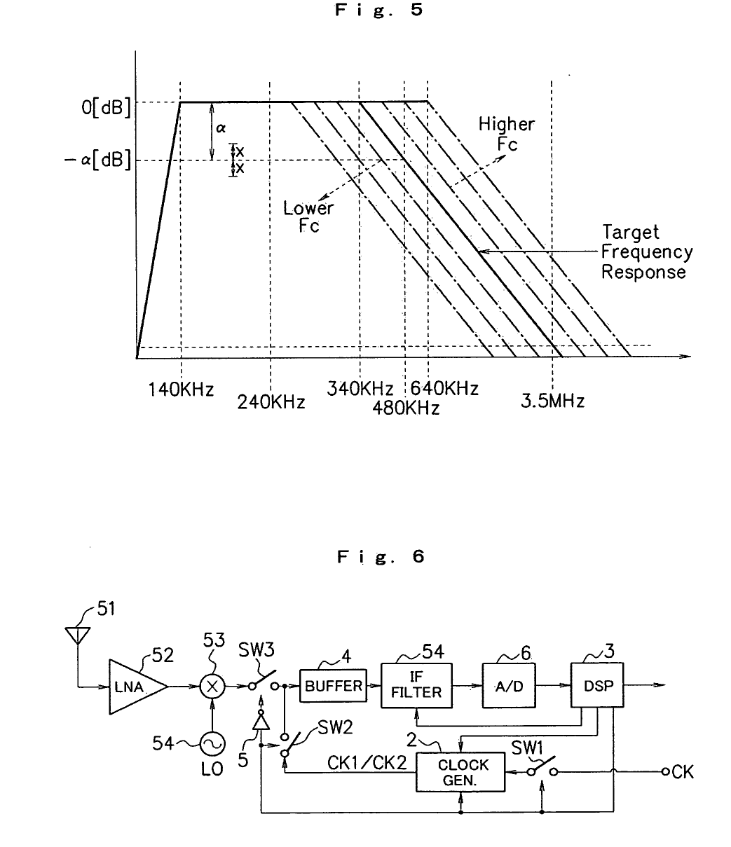

FIG. 4 is a diagram showing a configuration example of the filter circuit 1. In FIG. 4, reference character OA denotes a differential operational amplifier and reference characters R1 and R2 denote resistors serially connected to a plus input terminal of the differential operational amplifier OA. The resistors R1 has a configuration in which N (N is an integer of 2 or more) resister elements R₁₁, R₁₂, . . . , R_{1N} are serially connected. Resistor values of the resister elements R₁₁, R₁₂, . . . , R_{1N} may be identical or not. Similarly, the resistance R2 has a configuration in which N resister elements R₂₁, R₂₂, . . . , R_{2N} are serially connected. Resistor values of the resister elements R₂₁, R₂₂, . . . , R_{2N} may be identical or not.

Reference character CO denotes a capacitor connected to an input terminal IN, reference character C1 denotes a capacitor connected between the plus input terminal of the differential operational amplifier OA and the ground, and reference character C2 denotes a capacitor connected between an output terminal OUT of the differential operational amplifier OA and a connecting point of the resistances R1 and R2. An output of the differential operational amplifier OA is input to a minus input terminal of the differential operational amplifier OA in a negative feedback manner.

The filter circuit 1 shown in FIG. 4 is a secondary active filter comprising the differential operational amplifier OA, the resistances R1 and R2, and the capacitors C1 and C2, wherein the resistances R1 and R2 include a plurality of the resister elements R₁₁, R₁₂, . . . , R_{1N} and R₂₁, R₂₂, . . . , R_{2N} respectively.

Reference characters S₁₁, S₁₂, . . . , S_{1N-1} denote switches to select any of a plurality of the resister elements R₁₁, R₁₂, . . . , R_{1N} and reference characters S₂₁, S₂₂, . . . , S_{2N-1} denote switches to select any of a plurality of the resister elements R₂₁, R₂₂, . . . , R_{2N}. A plurality of the resister elements R₁₁, R₁₂, . . . , R_{1N} and a plurality of the switches S₁₁, S₁₂, . . . , S_{1N-1} are ladder-connected, and turning on any one of the switches selects a resister element to be serially connected. For example, turning on the first switch S₁₁ short-circuits the first resister element R₁₁ and serially connects the resister elements R₁₂, . . . , R_{1N} from the second resister element onward.

Similarly, a plurality of the resister elements R₂₁, R₂₂, . . . , R_{2N} and a plurality of the switches S₂₁, S₂₂, . . . , S_{2N-1} are ladder-connected, and turning on any one of the switches selects a resister element to be serially connected. For example, turning on the first switch S₂₁ short-circuits the first resister element R₂₁ and serially connects the resister elements R₂₂, . . . , R_{2N} from the second resister element onward.

Here, both of the i th (i=1 to N−1) switches among a plurality of the switches S₁₁, S_{12a, . . . , S}_{1N-1} and S₂₁, S₂₂, . . . , S_{2N-1} synchronize each other to be turned on. In this manner, turning on any one pair of switches S₁ᵢ and S₂ᵢ enables the resistor values of the resistances R1 and R2 connected to the differential operational amplifier OA to be variable.

Thus, a cutoff frequency f_{c} of the filter circuit 1 can be variable. Specifically, the cutoff frequency f_{c} of the filter circuit 1 is determined based on combined resistor values of serial connections of the resister elements selected from a plurality of the resister elements R₁₁, R₁₂, . . . , R_{1N} and R₂₁, R₂₂, . . . , R_{2N} by the switches S₁₁, S₁₂, . . . , S_{1N-1} and S₂₁, S₂₂, . . . , S_{2N-1}; and the capacitive values of the capacitors C1 and C2. Assume that the combined resistance values of the resistances R1 and R2 are respectively represented by R₁ and R₂, and the capacitive values of the capacitors C1 and C2 are respectively represented by C₁ and C₂; the cutoff frequency f_{c} of the filter circuit 1 is obtained by:

f_{c}=½π(R₁R₂C₁C₂)^{1/2}

Returning to FIG. 2, the A/D converter 6 converts a signal output from the filter circuit 1 into digital data and supplies it to the DSP 3. In the normal mode, the DSP 3 performs a digital signal process to the digital data input from the A/D converter 6 and outputs the resulting data outside.

Additionally, in the adjusting mode of the cutoff frequency, the DSP 3 compares a level LV1 of a signal output from the filter circuit 1 when the first frequency clock signal CK1 generated at the clock signal generator 2 is input to the filter circuit 1 with a level LV2 of a signal output from the filter circuit 1 when the second frequency clock signal CK2 generated at the clock signal generator 2 is input to the filter circuit 1; and controls the switches S₁₁, S₁₂, . . . , S_{1N-1} and S₂₁, S₂₂, . . . , S_{2N-1} depending on the comparing result. That is, the DSP 3 turns off all the switches S₁₁, S₁₂, . . . , S_{1N-1} and S₂₁, S₂₂, . . . , S_{2N-1} or turns on any one pair of the switches S₁ᵢ and S₂ᵢ by supplying switch control signals BP₁ to BP_{N-1} to the filter circuit 1.

To specifically describe the control of the switch, the DSP 3 first detects a difference β between the signal levels LV1 and LV2, and determines whether a value of the difference β is equal to a predetermined value α (a value corresponding to a difference between signal levels of 240 KHz and 480 KHz in a frequency characteristic indicating a desired cutoff frequency) or is within a predetermined tolerance x to the predetermined value α.

For example, in the case of constituting the filter circuit 1 with a frequency characteristic like a solid line shown in FIG. 5, if the level LV1 of a signal output from the filter circuit 1 is 0 dB when the clock signal CK1 of 240 KHz is input to the filter circuit 1 and the level LV2 of a signal output from the filter circuit 1 is −α dB (if β=α) when the clock signal CK2 of 480 KHz is input to the filter circuit 1, a desired cutoff frequency is to be obtained.

On the other hand, in the case where a frequency characteristic is shifted from the desired frequency characteristic like dotted lines due to manufacturing variations of resistors or capacitors, the level LV2 of a signal output from the filter circuit 1 is not −α dB (β≠α) when the clock signal CK2 of 480 KHz is input to the filter circuit 1, so that an error occurs. The DSP 3 determines whether the error is within the predetermined tolerance x. Specifically, if the tolerance is ±x, the DSP 3 determines whether a condition of α−x≦β≦α+x is satisfied or not. Then, if the condition is not satisfied, the DSP 3 determines which of the signal level LV2 and the predetermined value α is greater and switches selection states of the switches S₁₁, S₁₂, . . . , S_{1N-1} and S₂₁, S₂₂, . . . , S_{2N-1} depending on the determination result.

Here, when LV2>α, since an actual cutoff frequency is shifted higher than a desired cutoff frequency, switching the switches at more front stage sides (sides of the switches S₁₁ and S₁₂) than the present situation into the on-state increases the combined resistance values R₁ and R₂, thereby lowering the cutoff frequency. On the contrary, when LV2<α, since the actual cutoff frequency is shifted lower than the desired cutoff frequency, switching the switches at more subsequent stage sides (sides of the switches S_{1N-1} and S_{2N-1}) than the present situation into the on-state reduces the combined resistance values R₁ and R₂, thereby increasing the cutoff frequency.

When the difference β between the signal levels LV1 and LV2 is adjusted to be the predetermined value α or within the tolerance x, data indicating a selection state of each switch S₁₁, S₁₂, . . . , S_{1N-1} and S₂₁, S₂₂, . . . , S_{2N-1} is held in a not-shown memory, and the DSP 3 holds the selection state of each switch S₁₁, S₁₂, . . . , S_{1N-1}, and S₂₁, S₂₂, . . . , S_{2N-1} in accordance with the data. Because of this, the desired frequency characteristic is maintained constantly.

FIG. 6 is a diagram showing a configuration example of a radio receiver to which the circuit for adjusting a cutoff frequency of a filter according to the embodiment with the above configuration is applied. Note that, in FIG. 6, since some of the components with reference characters similar to the reference characters shown in FIG. 2 have similar functions, redundant description is omitted here.

The radio receiver shown in FIG. 6 receives an RF signal (high frequency signal) through an antenna 51 and supplies the received RF signal to an LNA (low noise amplifier) 52. The signal amplified at the LNA 52 is supplied to a mixer 53. The mixer 53 converts the RF signal into an IF signal (intermediate-frequency signal) by mixing the RF signal of a predetermined frequency band input from the LNA 52 and a local oscillation signal supplied from a local oscillator 54.

When a normal mode is set by a DSP 3, the IF signal generated at the mixer 53 is supplied to a buffer 4 through a third switch SW3. An IF filter 54 connected to a subsequent stage of the buffet 4, which corresponds to the filter circuit 1 described above, removes a signal of a close channel by a filtering process to the IF signal input from the buffer 4 and outputs the result to an A/D converter 6. The A/D converter 6 converts the IF signal input from the IF filter 54 into digital data and supplies it to the DSP 3. The DSP 3 performs a baseband process including a demodulation process to the input digital data.

On the other hand, when an adjusting mode of a cutoff frequency is set by the DSP 3, clock signals CK1 and CK2 sequentially generated at a clock signal generator 2 are supplied to the buffer 4 through a second switch SW2. The IF filter 54 performs the filtering process to the clock signals CK1/CK2 input from the buffer 4 and outputs the result to the A/D converter 6. The A/D converter 6 converts the signal input from the IF filter 54 into digital data and supplies it to the DSP 3. The DSP 3 controls switches S₁₁, S₁₂, . . . , S_{1N-1} and S₂₁, S₂₂, . . . , S_{2N-1} of the IF filter 54 (filer circuit 1) by using the input digital data (data indicating signal levels LV1 and LV2).

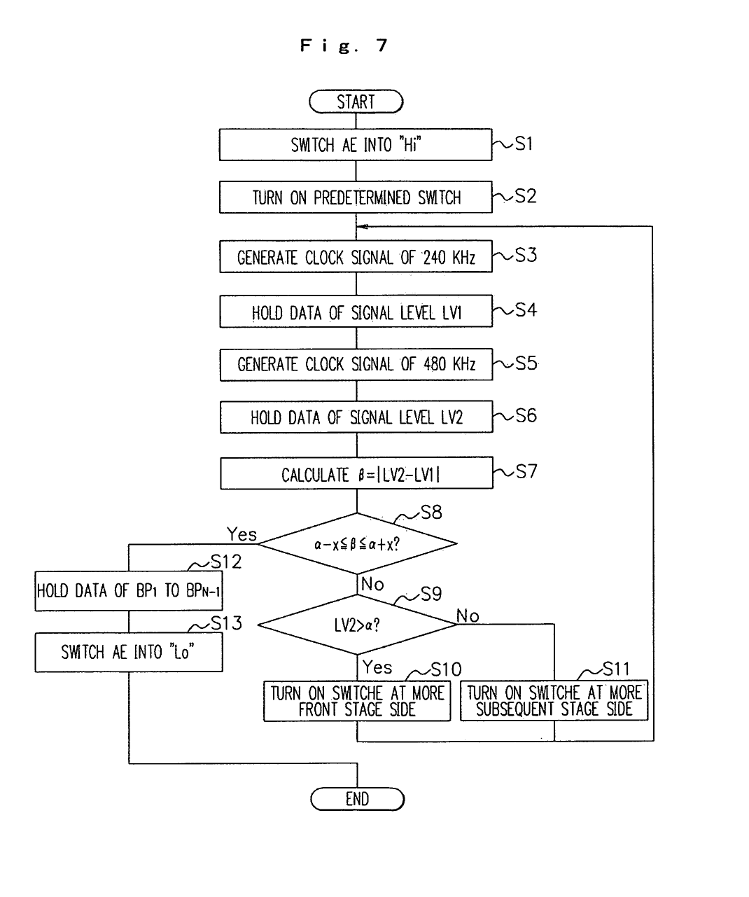

FIG. 7 is a flow chart showing an exemplary operation in the adjusting mode of the cutoff frequency. The DSP 3 first switches a mode control signal AE into “Hi” and sets the adjusting mode of the cutoff frequency (step S1). Also, the DSP 3 turns on a predetermined pair of switches S₁ᵢ and S₂ᵢ (for example, switches located substantially in the center) among a plurality of the switches S₁₁, S₁₂, . . . , S_{1N-1} provided corresponding to a resistance R1 and a plurality of the switches S₂₁, S₂₂, S_{2N-1} provided corresponding to a resistance R2 (step S2).

Next, the clock signal generator 2 generates the clock signal CK1 of 240 KHz in accordance with the control of the DSP 3 (step S3). The first frequency clock signal CK1 generated here is processed at the filter circuit 1 and the A/D converter 6, and supplied to the DSP 3. The DSP 3 detects the signal level LV1 based on data input from the A/D converter 6 and holds it in a not-shown memory (step S4).

Next, the clock signal generator 2 generates the clock signal CK2 of 480 KHz in accordance with the control of the DSP 3 (step S5). The second frequency clock signal CK2 generated here is processed at the filter circuit 1 and the A/D converter 6, and supplied to the DSP 3. The DSP 3 detects the signal level LV2 based on data input from the A/D converter 6, and holds it in the not-shown memory (step S6).

Then, the DSP 3 calculates a difference P between the signal levels LV1 and LV2 (step S7) and determines whether a value of the difference β is equal to a predetermined value α or within a predetermined tolerance ±x. Specifically, the DSP 3 determines whether a condition of α−x≦β≦α+x is satisfied or not (step S8). If the condition is not satisfied, the DSP 3 determines whether the signal level LV2 is greater than the predetermined value α or not (step S9).

If LV2>α, since an actual cutoff frequency is shifted higher than a desired cutoff frequency, the DSP 3 controls the switches at more front stage sides (sides of the switches S₁₁ and S₂₁) than the switches turned on in step S1 so as to be switched into the on-state (step S10). This increases combined resistance values R₁ and R₂, thereby lowering the cutoff frequency.

On the other hand, if LV2<α, since the actual cutoff frequency is shifted lower than the desired cutoff frequency, the DSP 3 controls the switches at more subsequent stage sides (sides of the switches S_{1N-1} and S_{2N-1}) than the switches turned on in step S1 so as to be switched into the on-state (step S11). This reduces the combined resistance values R₁ and R₂, thereby bringing the cutoff frequency higher.

After the process of step S10 or step S11, the processing returns to step S3 for repeating the similar process. The processing may return to step S5 instead of step S3. Like this repeating processing sequentially switches which switch to be turned on among the switches S₁₁, S₁₂, . . . , S_{1N-1} and S₂₁, S₂₂, . . . , S_{2N-1}. Then, if the condition of α−x≦β≦α+x is satisfied in step S8, the DSP 3 holds switch control signals BP₁ to BP_{N-1} at that time in the not-shown memory (step S12), and switches the mode control signal AE back to “Lo” (step S13). If the condition of step S8 is not satisfied even though the switches S₁₁, S₁₂, . . . , S_{1N-1} and S₂₁, S₂₂, . . . , S_{2N-1} are switched in any manner, an error processing is performed.

States of the switches S₁₁, S₁₂, . . . , S_{1N-1} and S₂₁, S₂₂, . . . , S_{2N-1} are established by holding the switch control signals BP₁ to BP_{N-1} in the memory in step 12. This memory may be a nonvolatile or a volatile memory. If a nonvolatile memory is used, once a cutoff frequency adjustment is performed, another adjustment is not required after that. If a volatile memory is used, a cutoff frequency adjustment is performed every time, for example, a power supply of the radio receiver is turned on. Note that, even if a nonvolatile memory is used, it is also possible to perform the adjustment again.

As described above in detail, according to the embodiment, it is possible to select an optimum resistor value of the filter circuit 1 by a digital signal processing with the DSP 3 so that a cutoff frequency of the filter circuit 1 can be appropriately adjusted.

In the embodiment, an example is described in which selecting any of a plurality of the resister elements R₁₁, R₁₂, . . . , R_{1N} and R₂₁, R₂₂, . . . , R_{2N} makes a resistor value variable, thereby adjusting a cutoff frequency of the filter circuit 1, however, the present invention is not limited thereto. For example, it is: also possible that a plurality of capacitors are provided and selecting any of the capacitors makes a capacitive value variable, thereby adjusting the cutoff frequency of the filter circuit 1.

Also, in the embodiment, an example is described in which 240 KHz and 480 KHz are used as frequencies for the clock signals CK1 and CK2 generated at the clock signal generator 2, however, the present invention is not limited to the frequencies.

Also, in the embodiment, the secondary active filter is described as an example of the filter circuit 1, however, the present invention is not limited thereto. For example, a primary or a higher-order active filter, or a passive filer may be used. Additionally, it can also be applied to various types of filters such as a Chebyshev filter, a Bessel filter and a biquad filter.

Also, in the embodiment, an example is described in which the circuit for adjusting a cutoff frequency is applied to the radio receiver, however, the present invention is not limited thereto. The circuit for adjusting a cutoff frequency can be applied to anything as long as it is an electronic circuit with a filter circuit including a capacitor and a resistor or an applied product thereof.

While the embodiment only shows a concrete example for carrying out the present invention, the technical scope of the present invention should not be limited thereto. Thus, various modifications and changes may be made thereto without departing from the spirit and the main features of the present invention.

### INDUSTRIAL APPLICABILITY

The present invention is useful for a circuit for adjusting a cutoff frequency of a filter circuit including a capacitor and a resistor.

1. A circuit for adjusting a cutoff frequency of a filter, comprising:
a filter circuit provided with a plurality of resister elements, a switch to select any of a plurality of the resister elements and a capacitor, whose cutoff frequency is determined by a resistor value of a resister element selected from a plurality of the resister elements by the switch and a capacitive value of the capacitor;
a clock signal generator generating a first frequency clock signal as a reference and a second frequency clock signal for adjusting; and
a signal processing part comparing a first level of a signal output from the filter circuit when the first frequency clock signal is input to the filter circuit with a second level of a signal output from the filter circuit when the second frequency clock signal is input to the filter circuit, and controlling the switch depending on the comparing result.

2. A circuit for adjusting a cutoff frequency of a filter, comprising:
a filter circuit provided with a plurality of capacitors, a switch to select any of a plurality of the capacitors and a resister element, whose cutoff frequency is determined by a capacitive value of a capacitor selected from a plurality of the capacitors by the switch and a resistor value of the resister element;
a clock signal generator generating a first frequency clock signal as a reference and a second frequency clock signal for adjusting; and
a signal processing part comparing a first level of a signal output from the filter circuit when the first frequency clock signal is input to the filter circuit with a second level of a signal output from the filter circuit when the second frequency clock signal is input to the filter circuit, and controlling the switch depending on the comparing result.

3. The circuit for adjusting a cutoff frequency of a filter according to claim 1,
the signal processing part determines whether a difference between the first level and the second level is within a predetermined value, and determines which of the second level and the predetermined value is greater if the difference is not within the predetermined value and controls the switch depending on the determination result.

4. The circuit for adjusting a cutoff frequency of a filter according to claim 1,
all of the filter circuit, the clock signal generator and the signal processing part are constituted by a CMOS process.

5. The circuit for adjusting a cutoff frequency of a filter according to claim 2,
the signal processing part determines whether a difference between the first level and the second level is within a predetermined value, and determines which of the second level and the predetermined value is greater if the difference is not within the predetermined value and controls the switch depending on the determination result.

6. The circuit for adjusting a cutoff frequency of a filter according to claim 2,
all of the filter circuit, the clock signal generator and the signal processing part are constituted by a CMOS process.
